(19) United States
(12) Patent Application Publication
(10) Pub. No.: US 2018/0031877 A1
(43) Pub. Date: Feb. 1, 2018

(54) LIQUID CRYSTAL DISPLAY

(71) Applicant: Wuhan China Star Optoelectronics Technology Co., Ltd., Wuhan City (CN)

(72) Inventor: Yafeng Li, Wuhan City (CN)

(21) Appl. No.: 14/914,653

(22) PCT Filed: Jan. 29, 2016
(86) PCT No.: PCT/CN2016/072775

§ 371 Date: Feb. 26, 2016

(30) Foreign Application Priority Data
Dec. 17, 2015 (CN) 201510957879.3

(51) Int. Cl. G02F 1/1335; G03F 7/00; G09G 3/36; G02F 1/1368

(52) U.S. Cl. CPC G02F 1/1335; G02F 1/1368; G02F 1/133514; G03F 7/0007; G09G 3/36; G02F 1/133621; G02F 1/1343

(57) ABSTRACT

The invention provides an LCD, wherein the color-resist layer, photo-spacer and TFT layer are disposed at the same second substrate of LC panel to achieve higher alignment precision by reducing offset between layers of second substrate; also, because the backlight module is disposed at the side near first substrate of LC panel and second substrate uses a top gate structure, when the backlight module light enters from first substrate side of LC panel, the gate shields the channel region of polysilicon layer to improve current leakage of second substrate; moreover, the shielding metal layer at the bottom of the second substrate side is made of a black metal, the shielding metal layer at the bottom can prevent reflection of light from second substrate side caused by metal to reduce contrast. As such, the present invention has a simple structure, and saves black matrix fabrication compared to conventional technology.

### BACKGROUND OF THE INVENTION

### 1. Field of the Invention

The present invention relates to the field of display, and in particular to a liquid crystal display (LCD).

### 2. The Related Arts

The liquid crystal display (LCD) provides the advantages of thin, low power consumption, radiation-free, and so on, and is widely applied to, such as, mobile phones, personal digital assistant (PDA), digital camera, computer monitors and notebook computers.

The conventional liquid crystal display devices on the market are mostly of the backlight type, comprising a case, a liquid crystal panel and a backlight module disposed inside the case. The traditional structure of the liquid crystal panel comprises a color filter (CF) substrate, a TFT array substrate, and a liquid crystal layer sandwiched between two substrates. The working principle is to apply a driving voltage to the two glass substrates to control the rotation of the liquid crystal molecules of the liquid crystal layer to refract the light from backlight to display.

LTPS technology is a new generation TFT substrate manufacturing technology, and the major difference between the conventional amorphous silicon (a-Si) technology and LTPS technology is that the LTPS provides that advantages of high response speed, high brightness, high-resolution and low power consumption. Because the LPTS has the high migration property, the ratio between the channel width W and the channel length L (W/L) of the TFT substrate switch when designing the pixels can be small so that the aperture ratio of corresponding to the pixels can be higher to provide market competitiveness.

Refer to FIG. 1 for a schematic view of a known LCD, which comprises: a liquid crystal (LC) panel 100, and a backlight module 200 disposed below the LC panel 100, the LC panel 100 comprising a CF substrate 110, a TFT array substrate 120 disposed opposite to the CF substrate 110, an LC layer sandwiched between the CF substrate 110 and the TFT array substrate 120, and a sealant to bond the CF substrate 110 and the TFT array substrate 120.

FIG. 2 is a schematic view showing the cross-sectional structure of the LC panel 100 of the LCD in FIG. 1, wherein the CF substrate 110 comprises a first base substrate 400, a black matrix 220 and a color-resist layer 340 disposed on the first base substrate 400, a first planarization layer 350 disposed on the color-resist layer 340, and a main photo-resist space 370 and an auxiliary photo-resist spacer 360 disposed on the first planarization layer 350; the TFT substrate 120 comprises a second base substrate 210, a shielding metal layer 390 disposed on the second base substrate 210, a first insulating layer 230 disposed on the second base substrate 210 and the shielding metal layer 390, a polysilicon layer 240 disposed on the first insulating layer 230, a second insulating layer 250 disposed on the first insulating layer 230 and the polysilicon layer 240, a gate 260 disposed on the second insulating layer 250, a third insulating layer 270 disposed on the second insulating layer 260 and the gate 260, a source and a drain (source/drain) 280 disposed on the third insulating layer 270, a second planarization layer 290 disposed on the third insulating layer 270 and the source/drain 280, a common electrode layer 300 disposed on the second planarization layer 290, a passivation layer 310 disposed on the common electrode layer 300, a pixel electrode layer 320 disposed on the passivation layer 310; the passivation layer 310 and the second planarization layer 290 being disposed with vias 500 at locations corresponding to and above the source/drain 280, the pixel electrode layer 320 connected through vias 500 to the source/drain 280.

In the above LCD, to prevent light leakage from the pixel edge, a black matrix 220 is disposed at the CF substrate 110 side to shield. The black matrix 220 can also prevent the problem of lowering the contrast of panel caused by the metal (mainly the source/drain 280) on TFT substrate 120 side reflecting the incident light from the CF substrate 110 side. The above problems mainly come from the known LCD being formed by combining the CF substrate 110 and the TFT substrate 120. As such, the alignment precision between the black matrix 220 on the CF substrate 110 side and the metal on TFT substrate 120 side. In the current process, it is impossible to achieve error-free alignment. With an error up to ±5 um, the actual aperture ratio of the LC panel will be very different from the design, and also a large deviation will exist among the aperture ratios of the LCDs from the same manufactured batch.

### SUMMARY OF THE INVENTION

The object of the present invention is to provide an LCD with higher alignment precision and aperture ratio.

To achieve the above object, the present invention provides an LCD, which comprises: a liquid crystal (LC) panel, and a backlight module disposed below the LC panel, the LC panel comprising a first substrate, a second substrate disposed opposite to the first substrate, an LC layer sandwiched between the first substrate and the second substrate, and a sealant to bond the first substrate and the second substrate; the second substrate comprising a base substrate, a shielding metal layer disposed on the base substrate, a first insulating layer disposed on the base substrate and the shielding metal layer, a TFT layer disposed on the first insulating layer, a first passivation layer disposed on the TFT layer, a color-resist layer disposed on the first passivation layer, a first planarization layer disposed on the color-resist layer, and a photo-resist spacer disposed on the first planarization layer; the TFT layer comprising a polysilicon layer disposed on the first insulating layer, a second insulating layer disposed on the first insulating layer and the polysilicon layer, a gate disposed on the second insulating layer, a third insulating layer disposed on the second insulating layer and the gate, a source and a drain (source/drain) disposed on the third insulating layer, a second planarization layer disposed on the third insulating layer and the source/drain, a common electrode layer disposed on the second planarization layer, a second passivation layer disposed on the second planarization layer and the common electrode layer, a pixel electrode layer disposed on the second passivation layer; the second passivation layer and the second planarization layer being disposed with vias at locations corresponding to and above the source/drain, the pixel electrode layer connected through vias to the source/drain.

The material of the shielding metal layer is chromium.

The first substrate and the base substrate are both glass substrates.

The backlight module is disposed at the side near the first substrate of the LC panel.

The color-resist layer comprises a plurality of spaced red color-resist blocks, a plurality of spaced green color-resist blocks, and a plurality of spaced blue color-resist block; the shielding metal layer covers completely over the space between two adjacent color-resist blocks on the color-resist layer in the horizontal direction.

The first insulating layer, the second insulating layer, and the third insulating layer are made of a silicon nitride layer, a silicon oxide layer, or a composite structure of both; the common electrode layer and the pixel electrode layer are made of indium tin oxide (ITO).

The photo-resist spacer comprises a primary photo-resist spacer and an auxiliary photo-resist spacer; the main photo-resist spacer is in contact with the first substrate; and a gap exists between the auxiliary photo-resist spacer and the first substrate.

The TFT layer also comprises a plurality of data lines disposed on the third insulating layer.

The shielding metal layer completely shields the polysilicon layer, the gate and the source/drain in the horizontal direction.

The present invention also provides an LCD, which comprises: a liquid crystal (LC) panel, and a backlight module disposed below the LC panel, the LC panel comprising a first substrate, a second substrate disposed opposite to the first substrate, an LC layer sandwiched between the first substrate and the second substrate, and a sealant to bond the first substrate and the second substrate; the second substrate comprising a base substrate, a shielding metal layer disposed on the base substrate, a first insulating layer disposed on the base substrate and the shielding metal layer, a TFT layer disposed on the first insulating layer, a first passivation layer disposed on the TFT layer, a color-resist layer disposed on the first passivation layer, a first planarization layer disposed on the color-resist layer, and a photo-resist spacer disposed on the first planarization layer; wherein the TFT layer comprises a polysilicon layer disposed on the first insulating layer, a second insulating layer disposed on the first insulating layer and the polysilicon layer, a gate disposed on the second insulating layer, a third insulating layer disposed on the second insulating layer and the gate, a source and a drain (source/drain) disposed on the third insulating layer, a second planarization layer disposed on the third insulating layer and the source/drain, a common electrode layer disposed on the second planarization layer, a second passivation layer disposed on the second planarization layer and the common electrode layer, a pixel electrode layer disposed on the second passivation layer; the second passivation layer and the second planarization layer being disposed with vias at locations corresponding to and above the source/drain, the pixel electrode layer connected through vias to the source/drain; wherein the material of the shielding metal layer is chromium; wherein the first substrate and the base substrate are both glass substrates; wherein the backlight module is disposed at the side near the first substrate of the LC panel; wherein the color-resist layer comprises a plurality of spaced red color-resist blocks, a plurality of spaced green color-resist blocks, and a plurality of spaced blue color-resist block; the shielding metal layer covers completely over the space between two adjacent color-resist blocks on the color-resist layer in the horizontal direction.

Compared to the known techniques, the present invention provides the following advantages: the present invention provides an LCD, wherein the color-resist layer, photo-spacer and TFT layer are disposed at the same second substrate of the LC panel so that when fabricating each layer on the second substrate, a higher alignment precision can be obtained by using the reserved markers on the mask to align with the previous layer in fabrication process; at the same time, because the backlight module is disposed at the side near the first substrate of the LC panel and the second substrate uses a top gate structure, when the light of the backlight module enters from the first substrate side of the LC panel, the gate can shield the channel region of the polysilicon layer to improve the current leakage of the second substrate and avoid the current leakage caused by light; moreover, if the shielding metal layer at the bottom of the second substrate side is made of a black metal, such as, chromium, the shielding metal layer at the bottom can prevent reflection of light from the second substrate side caused by metal to reduce the contrast. As such, the present invention has a simple structure, saves the black matrix fabrication and provides higher alignment precision and aperture ratio.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a cross-sectional view showing the structure of a known LCD;

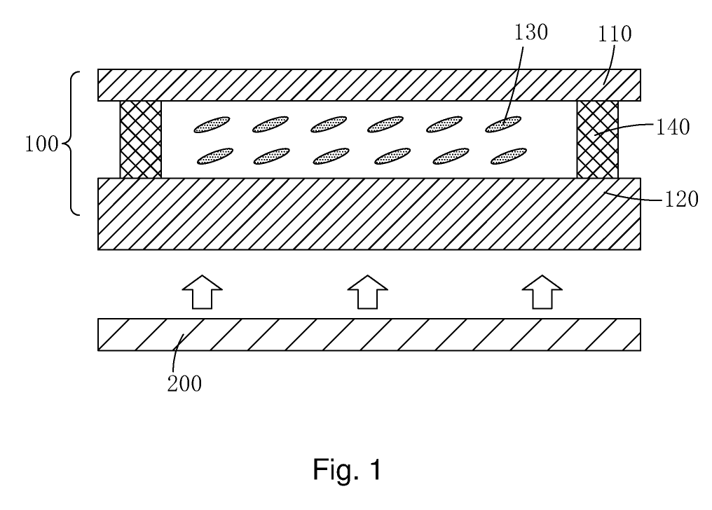

FIG. 2 is a cross-sectional view showing the structure of the LC panel of a known LCD in FIG. 1;

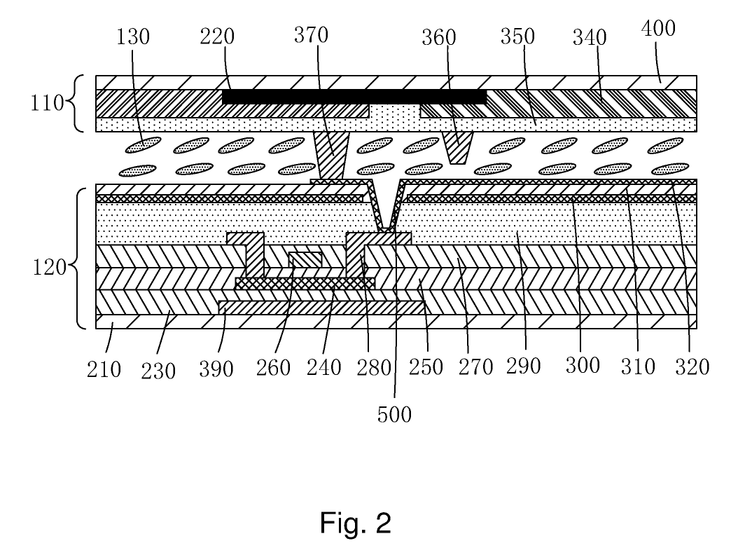

FIG. 3 is a cross-sectional view showing the structure of the LCD provided by an embodiment of the present invention;

FIG. 4 is a schematic view showing the structure of the LC panel at the TFT of the LCD in FIG. 3; and

FIG. 5 is a schematic view showing the structure of the LC panel at the data lines of the LCD in FIG. 3.

### DETAILED DESCRIPTION OF THE PREFERRED EMBODIMENTS

To further explain the technical means and effect of the present invention, the following refers to embodiments and drawings for detailed description.

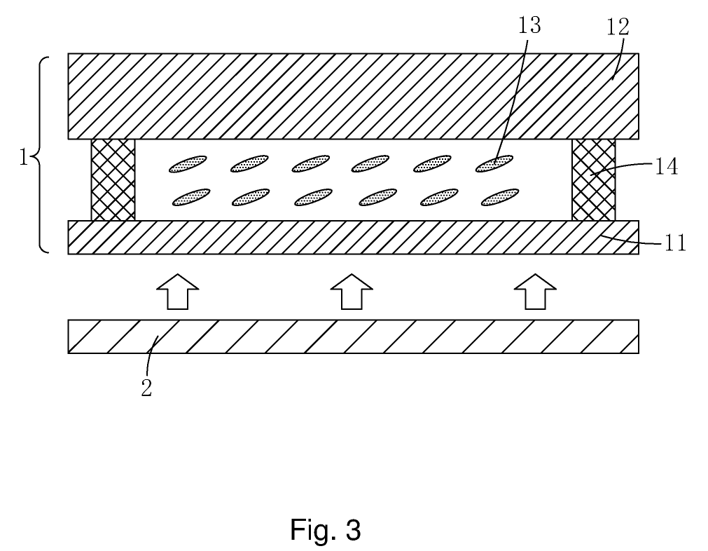

Refer to FIGS. 3-5. The present invention provides a LCD, which comprises: a liquid crystal (LC) pane 1, and a backlight module 2 disposed below the LC panel 1.

As shown in FIG. 3, the LC panel comprises a first substrate 11, a second substrate 12 disposed opposite to the first substrate 11, an LC layer 13 sandwiched between the first substrate 11 and the second substrate 12, and a sealant 14 to bond the first substrate 11 and the second substrate 12.

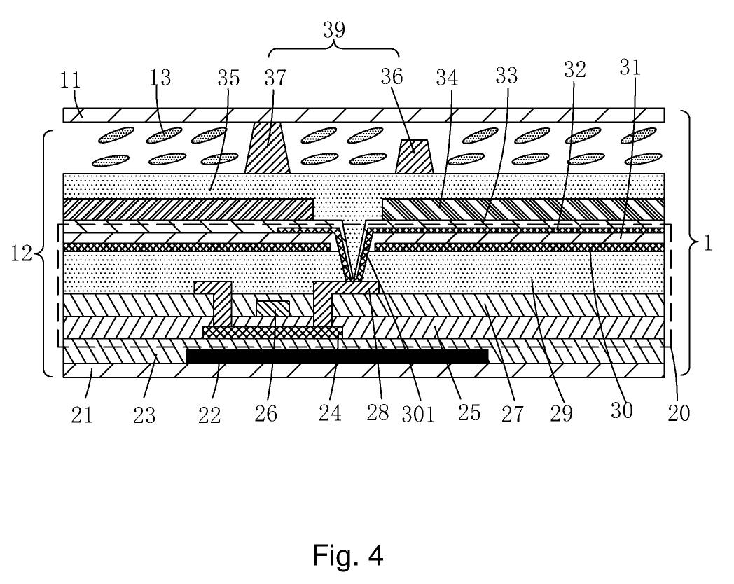

As shown in FIG. 4, the second substrate 12 comprises a base substrate 21, a shielding metal layer 22 disposed on the base substrate 21, a first insulating layer 23 disposed on the base substrate 21 and the shielding metal layer 22, a TFT layer 20 disposed on the first insulating layer 23, a first passivation layer 33 disposed on the TFT layer 20, a color-resist layer 34 disposed on the first passivation layer 33, a first planarization layer 35 disposed on the color-resist layer 34, and a photo-resist spacer 39 disposed on the first planarization layer 35.

Because the color-resist layer 34, photo-spacer 39 and TFT layer 20 are disposed at the same second substrate 12 of the LC panel 1 so that when fabricating each layer on the second substrate 12, a higher alignment precision can be obtained by using the reserved markers on the mask to align with the previous layer in fabrication process to achieve a smaller offset between layers. The precision can be around ±0.6 um.

Specifically, the first substrate 11 and the base substrate 21 are both glass substrates.

Specifically, the backlight module 2 is disposed at the side near the first substrate 11 of the LC panel 1.

Specifically, the color-resist layer 34 comprises a plurality of spaced red color-resist blocks, a plurality of spaced green color-resist blocks, and a plurality of spaced blue color-resist block; the shielding metal layer 22 covers completely over the space between two adjacent color-resist blocks on the color-resist layer 34 in the horizontal direction so as to replace a black matrix to prevent the pixel light leakage.

Specifically, the TFT layer 20 comprises: a polysilicon layer 24 disposed on the first insulating layer 23, a second insulating layer 25 disposed on the first insulating layer 23 and the polysilicon layer 24, a gate 26 disposed on the second insulating layer 25, a third insulating layer 27 disposed on the second insulating layer 25 and the gate 26, a source and a drain (source/drain) 28 disposed on the third insulating layer 27, a second planarization layer 29 disposed on the third insulating layer 27 and the source/drain 28, a common electrode layer 30 disposed on the second planarization layer 29, a second passivation layer 31 disposed on the second planarization layer 29 and the common electrode layer 30, a pixel electrode layer 32 disposed on the second passivation layer 31; the second passivation layer 31 and the second planarization layer 29 being disposed with vias 301 at locations corresponding to and above the source/drain 28, the pixel electrode layer 32 connected through vias 301 to the source/drain 28.

Because the backlight module 2 is disposed at the side near the first substrate 11 of the LC panel 1 and the second substrate 12 uses a top gate structure, when the light of the backlight module 2 enters from the first substrate 11 side of the LC panel 1, the gate 26 can shield the channel region of the polysilicon layer 24 to improve the current leakage of the second substrate 12 and avoid the current leakage caused by light.

Specifically, the shielding metal layer 22 completely shields the polysilicon layer 24, the gate 26 and the source/drain 28 in the horizontal direction. Therefore, when an external light enters from the bottom of the second substrate 12, the shielding metal layer 22 at the bottom of the second substrate 12 can shield the light and the TFT elements of the second substrate 12 from current leakage caused by channel lighting.

At the same time, by disposing the shielding metal layer 22 at the bottom of the second substrate 12, the shielding metal layer 22 can also prevent reflection of light from the second substrate 12 side caused by metal, such as, source/drain 28, to reduce the contrast.

Specifically, the shielding metal layer 22 is made of a black metal; and preferably, the material of the shielding metal layer is chromium.

Specifically, the first insulating layer 23, the second insulating layer 25, and the third insulating layer 27 are made of a silicon nitride layer, a silicon oxide layer, or a composite structure of both.

Specifically, the photo-resist spacer 39 comprises a primary photo-resist spacer 37 and an auxiliary photo-resist spacer 36; the main photo-resist spacer 37 is in contact with the first substrate 11; and a gap exists between the auxiliary photo-resist spacer 36 and the first substrate 11.

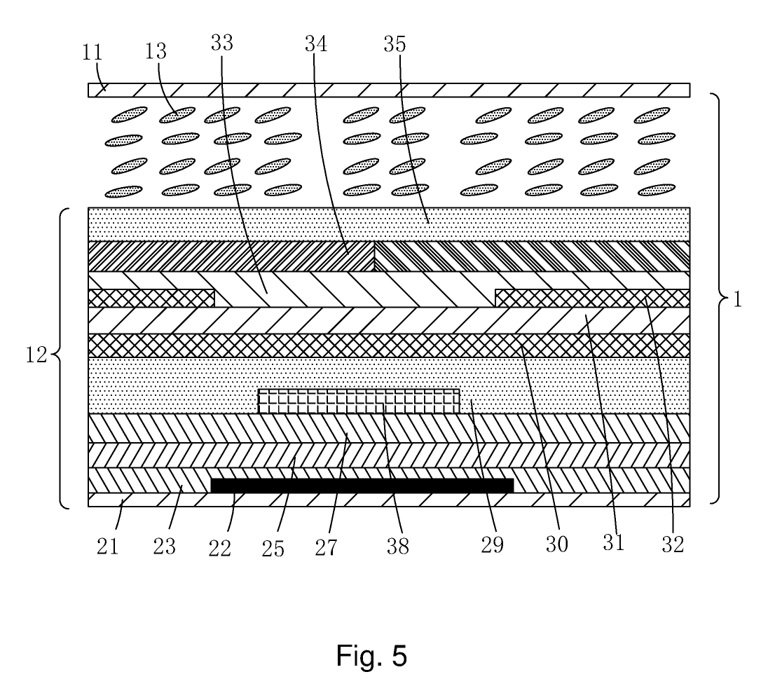

Specifically, as shown in FIG. 5, the TFT layer 20 also comprises a plurality of data lines 38 disposed on the third insulating layer 27.

Specifically, the common electrode layer 30 and the pixel electrode layer 32 are made of indium tin oxide (ITO).

In summary, the present invention provides an LCD, wherein the color-resist layer, photo-spacer and TFT layer are disposed at the same second substrate of the LC panel so that when fabricating each layer on the second substrate, a higher alignment precision can be obtained by using the reserved markers on the mask to align with the previous layer in fabrication process; at the same time, because the backlight module is disposed at the side near the first substrate of the LC panel and the second substrate uses a top gate structure, when the light of the backlight module enters from the first substrate side of the LC panel, the gate can shield the channel region of the polysilicon layer to improve the current leakage of the second substrate and avoid the current leakage caused by light; moreover, if the shielding metal layer at the bottom of the second substrate side is made of a black metal, such as, chromium, the shielding metal layer at the bottom can prevent reflection of light from the second substrate side caused by metal to reduce the contrast. As such, the present invention has a simple structure, saves the black matrix fabrication and provides higher alignment precision and aperture ratio.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A liquid crystal display (LCD), which comprises: a liquid crystal (LC) panel, and a backlight module disposed below the LC panel;
the LC panel comprising a first substrate, a second substrate disposed opposite to the first substrate, an LC layer sandwiched between the first substrate and the second substrate, and a sealant to bond the first substrate and the second substrate;
the second substrate comprising a base substrate, a shielding metal layer disposed on the base substrate, a first insulating layer disposed on the base substrate and the shielding metal layer, a TFT layer disposed on the first insulating layer, a first passivation layer disposed on the TFT layer, a color-resist layer disposed on the first passivation layer, a first planarization layer disposed on the color-resist layer, and a photo-resist spacer disposed on the first planarization layer.

2. The LCD as claimed in claim 1, wherein the TFT layer comprises a polysilicon layer disposed on the first insulating layer, a second insulating layer disposed on the first insulating layer and the polysilicon layer, a gate disposed on the second insulating layer, a third insulating layer disposed on the second insulating layer and the gate, a source and a drain (source/drain) disposed on the third insulating layer, a second planarization layer disposed on the third insulating layer and the source/drain, a common electrode layer disposed on the second planarization layer, a second passivation layer disposed on the second planarization layer and the common electrode layer, a pixel electrode layer disposed on the second passivation layer; the second passivation layer and the second planarization layer being disposed with vias at locations corresponding to and above the source/drain, the pixel electrode layer connected through vias to the source/drain.

3. The LCD as claimed in claim 1, wherein the material of the shielding metal layer is chromium.

4. The LCD as claimed in claim 1, wherein the first substrate and the base substrate are both glass substrates.

5. The LCD as claimed in claim 1, wherein the backlight module is disposed at the side near the first substrate of the LC panel.

6. The LCD as claimed in claim 1, wherein the color-resist layer comprises, arranged in a spaced manner, a plurality of red color-resist blocks, a plurality of green color-resist blocks, and a plurality of blue color-resist block; the shielding metal layer covers completely over the space between two adjacent color-resist blocks on the color-resist layer in the horizontal direction.

7. The LCD as claimed in claim 2, wherein the first insulating layer, the second insulating layer, and the third insulating layer are made of a silicon nitride layer, a silicon oxide layer, or a composite structure of both; the common electrode layer and the pixel electrode layer are made of indium tin oxide (ITO).

8. The LCD as claimed in claim 2, wherein the photo-resist spacer comprises a primary photo-resist spacer and an auxiliary photo-resist spacer; the main photo-resist spacer is in contact with the first substrate;
and a gap exists between the auxiliary photo-resist spacer and the first substrate.

9. The LCD as claimed in claim 2, wherein the TFT layer also comprises a plurality of data lines disposed on the third insulating layer.

10. The LCD as claimed in claim 2, wherein the shielding metal layer completely shields the polysilicon layer, the gate and the source/drain in the horizontal direction.

11. A liquid crystal display (LCD), which comprises: a liquid crystal (LC) panel, and a backlight module disposed below the LC panel;
the LC panel comprising a first substrate, a second substrate disposed opposite to the first substrate, an LC layer sandwiched between the first substrate and the second substrate, and a sealant to bond the first substrate and the second substrate;
the second substrate comprising a base substrate, a shielding metal layer disposed on the base substrate, a first insulating layer disposed on the base substrate and the shielding metal layer, a TFT layer disposed on the first insulating layer, a first passivation layer disposed on the TFT layer, a color-resist layer disposed on the first passivation layer, a first planarization layer disposed on the color-resist layer, and a photo-resist spacer disposed on the first planarization layer;
wherein the TFT layer comprises a polysilicon layer disposed on the first insulating layer, a second insulating layer disposed on the first insulating layer and the polysilicon layer, a gate disposed on the second insulating layer, a third insulating layer disposed on the second insulating layer and the gate, a source and a drain (source/drain) disposed on the third insulating layer, a second planarization layer disposed on the third insulating layer and the source/drain, a common electrode layer disposed on the second planarization layer, a second passivation layer disposed on the second planarization layer and the common electrode layer, a pixel electrode layer disposed on the second passivation layer; the second passivation layer and the second planarization layer being disposed with vias at locations corresponding to and above the source/drain, the pixel electrode layer connected through vias to the source/drain;
wherein the material of the shielding metal layer is chromium;
wherein the first substrate and the base substrate are both glass substrates;
wherein the backlight module is disposed at the side near the first substrate of the LC panel;
wherein the color-resist layer comprises, arranged in a spaced manner, a plurality of red color-resist blocks, a plurality of green color-resist blocks, and a plurality of blue color-resist block; the shielding metal layer covers completely over the space between two adjacent color-resist blocks on the color-resist layer in the horizontal direction.

12. The LCD as claimed in claim 11, wherein the first insulating layer, the second insulating layer, and the third insulating layer are made of a silicon nitride layer, a silicon oxide layer, or a composite structure of both; the common electrode layer and the pixel electrode layer are made of indium tin oxide (ITO).

13. The LCD as claimed in claim 11, wherein the photo-resist spacer comprises a primary photo-resist spacer and an auxiliary photo-resist spacer; the main photo-resist spacer is in contact with the first substrate;
and a gap exists between the auxiliary photo-resist spacer and the first substrate.

14. The LCD as claimed in claim 11, wherein the TFT layer also comprises a plurality of data lines disposed on the third insulating layer.

15. The LCD as claimed in claim 11, wherein the shielding metal layer completely shields the polysilicon layer, the gate and the source/drain in the horizontal direction.
